(19) United States
(12) Patent Application Publication
(10) Pub. No.: US 2024/0379608 A1
(43) Pub. Date: Nov. 14, 2024

(54) SEMICONDUCTOR MODULE AND METHOD OF MANUFACTURING SEMICONDUCTOR MODULE

(71) Applicant: FUJI ELECTRIC CO., LTD., Kawasaki-shi (JP)

(72) Inventors: Yuta TAKEUCHI, Matsumoto-city (JP); Yoshiaki TAKAHASHI, Matsumoto-city (JP)

(73) Assignee: FUJI ELECTRIC CO., LTD., Kawasaki-shi (JP)

(21) Appl. No.: 18/784,729

(22) Filed: Jul. 25, 2024

Related U.S. Application Data
(63) Continuation of application No. PCT/JP2023/024844, filed on Jul. 4, 2023.

(30) Foreign Application Priority Data
Aug. 1, 2022 (JP) 2022-122882

(51) Int. Cl. H01L 23/00; H01L 23/31; H01L 23/367; H01L 23/498

(52) U.S. Cl. CPC H01L 24/29; H01L 23/3171; H01L 23/49822; H01L 24/32; H01L 24/83; H01L 23/3672; H01L 2224/29111; H01L 2224/2912; H01L 2224/29139; H01L 2224/29147; H01L 2224/32225; H01L 2224/83026

(57) ABSTRACT

A semiconductor module, including: a stacked substrate; a semiconductor device element mounted on the stacked substrate, the semiconductor device element having an Ni layer at a back surface thereof; and a solder bonding the back surface of the semiconductor device element to the stacked substrate. The solder is formed of a composition containing: Sb in a range of more than 6 mass % but not more than 8.5 mass %, Ag in a range of 2 mass % to 4.5 mass %, Cu in a range of 1.25 mass % to 2.0 mass %, and Sn as a remaining portion thereof.

### CROSS REFERENCE TO RELATED APPLICATIONS

This is a continuation application of International Application PCT/JP2023/024844 filed on Jul. 4, 2023 which claims priority from a Japanese Patent Application No. 2022-122882 filed on Aug. 1, 2022, the contents of which are incorporated herein by reference.

### BACKGROUND OF THE INVENTION

### 1. Field of the Invention

Embodiments of the present invention relate to a semiconductor module and a method of manufacturing a semiconductor module.

### 2. Description of the Related Art

A power semiconductor module has one or more power semiconductor chips (also referred to as semiconductor device elements), configures a part of or all conversion connections, and is power semiconductor device having a structure in which: the one or more power semiconductor chips are electrically insulated from a stacked substrate having a conductive plate for wiring, and the one or more power semiconductor chips are electrically insulated from a metal substrate constituting a heat sink. Power semiconductor modules are used in industrial applications such as in motor-drive control inverters. Furthermore, in recent years, power semiconductor modules have come to be widely used in automotive motor-drive control inverters. There is demand for automotive motor-drive control inverters to be small in size and light-weight to improve fuel efficiency and to be reliable long-term under high-temperature operation due to being disposed in a vicinity of a drive motor in an engine room.

In this case, due to installation space constraints, there is demand for automotive power semiconductor modules to be smaller in size and lighter in weight compared to industrial power semiconductor modules. Further, output power density for driving the motor is high and thus, semiconductor chip temperature is high during operation and due to this high thermal stress, demand for long-term reliability during high-temperature operation is increasing. Thus, there is demand for a power semiconductor module structure having long-term reliability during high-temperature operation.

FIG. 5 is a cross-sectional view depicting a configuration of a power semiconductor module with a conventional structure. As depicted in FIG. 5, a power semiconductor module 150 has a power semiconductor chip 101, a stacked substrate 105, and a cooling device 126. The power semiconductor chip 101 is a power semiconductor chip such as a MOSFET, an IGBT, or a diode, and a chip bonding layer 127 bonds the power semiconductor chip 101 on the stacked substrate 105 by solder. The stacked substrate 105 refers to a structure in which a first conductive plate 103 containing, for example, copper is provided on a front surface of an insulating substrate 102 such as a ceramic substrate while a second conductive plate 104 containing, for example, copper is provided on a back surface of the insulating substrate 102. A cooling device bonding layer 128 bonds the cooling device 126 to the stacked substrate 105 by solder.

While not depicted, the power semiconductor module 150 is bonded to a case (not depicted) and has a metal terminal (not depicted) for outputting signals externally and metal wiring (not depicted) electrically connecting the power semiconductor chip 101 and the metal terminal. Further, in an instance of a MOSFET, a source electrode pad is formed as a power terminal electrode pad (current supply terminal) at the surface of the power semiconductor chip 101. Further, a conductive connecting member such as a lead frame, metal wiring, etc. is disposed as an output terminal from the power terminal electrode pad. In an instance of a lead frame, a bonding layer such as solder bonds the lead frame and the power semiconductor chip 101. These members may be mounted in plural in a single semiconductor device. The power semiconductor module 150 is fitted with a cover (not depicted) to which the case is attached and through which the metal terminal penetrates and protrudes externally. The case is filled with an encapsulant (non-depicted encapsulating resin) that insulates and protects the stacked substrate 105 and the power semiconductor chip 101 on the substrate.

Further, in a known solder joint, a solder alloy layer has an alloy composition containing, in mass percent (mass %), Ag: 2% to 4%, Cu: 0.6% to 2%, Sb: 9.0% to 12%, and Ni: 0.005% to 1% with the remaining being Sn, whereby separation of a back metal and a solder alloy during formation of the solder joint is suppressed and damage of electronic components due to chip cracking, scattering of molten solder, and non-wetting of solder alloy is suppressed (for example, refer to International Publication No. WO 2019/088068).

### SUMMARY OF THE INVENTION

According to an embodiment of the present invention, a semiconductor module includes: a stacked substrate; a semiconductor device element mounted on the stacked substrate, the semiconductor device element having an Ni layer at a back surface thereof; and a solder bonding the back surface of the semiconductor device element to the stacked substrate, the solder being formed of a composition containing: Sb in a range of more than 6 mass % but not more than 8.5 mass %, Ag in a range of 2 mass % to 4.5 mass %, Cu in a range of 1.25 mass % to 2.0 mass %, and Sn as a remaining portion thereof.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a configuration of a power semiconductor module according to an embodiment.

FIG. 2 is a cross-sectional view depicting a bonding layer constituted by solder and between a first conductive plate and power semiconductor chips of the power semiconductor module according to the embodiment.

FIG. 3A is a cross-sectional view depicting an Ni residual film of a bonding layer constituted by solder obtained by adding Cu of 0 mass % to a Sn—Sb—Ag based solder.

FIG. 3B is a cross-sectional view depicting the Ni residual film of the bonding layer constituted by solder obtained by adding Cu of 0.9 mass % to the Sn—Sb—Ag based solder.

FIG. 3C is a cross-sectional view depicting the Ni residual film of the bonding layer constituted by solder obtained by adding Cu of 2.0 mass % to the Sn—Sb—Ag based solder.

FIG. 4 is a table showing evaluation results for power semiconductor modules of comparison examples and examples, for each solder composition.

FIG. 5 is a cross-sectional view depicting a configuration of a power semiconductor module with a conventional structure.

FIG. 6 is an enlarged view of a region S of the power semiconductor module with the conventional structure in FIG. 5.

FIG. 7 is a cross-sectional view depicting a bonding layer constituted by solder, between a power semiconductor chip and a first conductive plate of a conventional power semiconductor module, under normal conditions.

FIG. 8 is a cross-sectional view depicting the bonding layer constituted by solder, between the power semiconductor chip and the first conductive plate of the conventional power semiconductor module, in a case of a defect.

### DETAILED DESCRIPTION OF THE INVENTION

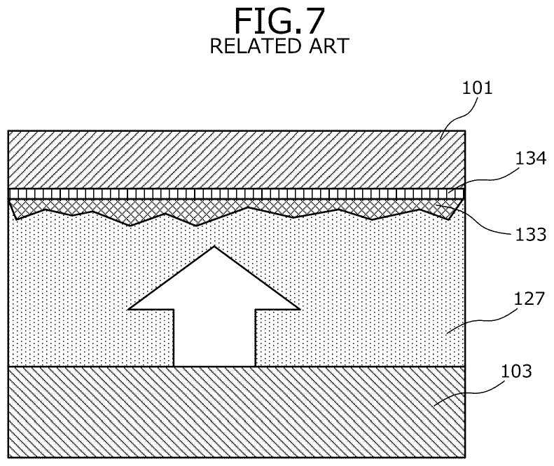

FIG. 6 is an enlarged view of a region S of the power semiconductor module with the conventional structure in FIG. 5. In FIG. 6, the structure between the power semiconductor chip 101 and the chip bonding layer 127 is depicted. A metal electrode 129 provided at the back surface of the power semiconductor chip 101 contains a AlSi (aluminum-silicon alloy) when the semiconductor is silicon (Si) and contains Ni (nickel) when the semiconductor is silicon carbide (SiC); and a Ti (titanium) layer 130, an Ni layer 131, and an Au (gold) layer 132 are stacked in the order stated between the metal electrode 129 and the chip bonding layer 127.

The Ti layer 130 is a barrier layer that prevents reaction between the chip bonding layer 127 and the metal electrode 129 thereabove and is provided having a thickness in a range of, for example, about 0.1 μm to 0.8 μm. Further, the Ni layer 131 is provided having a thickness in a range of about 0.2 μm to 1.2 μm to ensure wettability of the chip bonding layer 127. The Au layer 132 is provided having a thickness in a range of about 20 nm to 100 nm to prevent oxidation. The chip bonding layer 127 is solder containing Sn (tin).

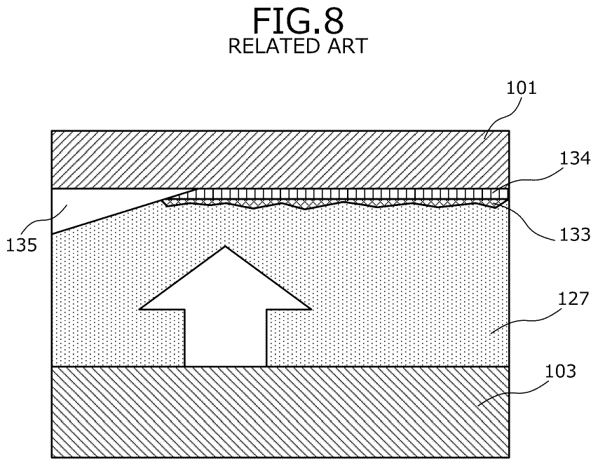

FIG. 7 is a cross-sectional view depicting a bonding layer constituted by solder, between a power semiconductor chip and a first conductive plate of a conventional power semiconductor module, under normal conditions. In this instance, as indicated by an arrow in FIG. 7, Cu diffuses from the first conductive plate 103 and forms a SnCu alloy 133 between the Ni layer 131 (134) and the chip bonding layer 127, whereby diffusion of the Ni layer 131 (134) is suppressed and an Ni residual film 134 of 0.1 μm or more remains. The Au layer 132 is not more than 20 nm and nearly disappears at the time of bonding.

FIG. 8 is a cross-sectional view depicting the bonding layer constituted by solder, between the power semiconductor chip and the first conductive plate of the conventional power semiconductor module, in a case of a defect. In this instance, the diffusion of Cu from the first conductive plate 103 as indicated by an arrow in FIG. 8 is slow, whereby the SnCu alloy 133 is insufficiently formed between the Ni layer 131 (134) and the chip bonding layer 127 or Ni from the Ni layer 131 (134) quickly diffuses in the chip bonding layer 127 (Sn solder) thereby generating a SnNi alloy, whereby the Ni residual film 134 is partially lost. As a result, the Ti layer 130, which has low bond-ability (solder wettability) with the solder, is in contact with the solder, an empty region (void) 135 occurs and a problem arises in that reliability of the power semiconductor module decreases. This phenomenon is particularly pronounced in an instance of the first conductive plate 103 in which an Ni alloy layer (plating layer) is formed at the surface because supply of Cu in the chip bonding layer 127 is difficult.

Embodiments of a semiconductor module and a method of manufacturing a semiconductor module according to the present invention are described in detail with reference to the accompanying drawings. However, the present invention is not limited by the embodiments described herein.

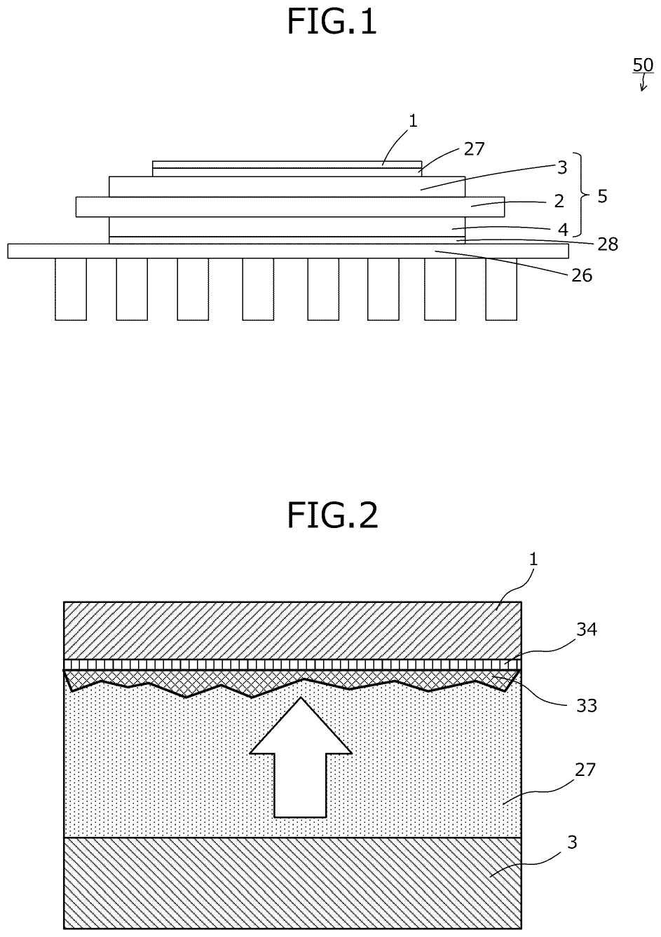

FIG. 1 is a cross-sectional view depicting a configuration of a power semiconductor module according to an embodiment. In a power semiconductor module 50, a stacked substrate 5 is formed by disposing, at one surface, that is, a front surface, of an insulating substrate 2, a first conductive plate 3 containing copper or the like, and disposing, at the other surface, that is, a back surface, of the insulating substrate 2, a second conductive plate 4 containing copper or the like. At a front surface of the first conductive plate 3 of the stacked substrate 5, multiple power semiconductor chips 1 are mounted via a chip bonding layer 27. At a back surface of the second conductive plate 4 of the stacked substrate 5, a cooling device 26 is mounted via a cooling device bonding layer 28.

In the power semiconductor module 50, a metal terminal (not depicted) for outputting signals externally is bonded in a case (not depicted). Furthermore, at front surfaces (for example, source electrode pad) of the power semiconductor chips 1, a conductive connecting member such as a pin-type terminal, a lead frame, etc. is mounted via metal wiring (not depicted) such as aluminum wires (bonding wires), a bonding layer (not depicted), etc. Further, the power semiconductor chips 1 and the metal terminals are electrically connected by metal wiring such as aluminum wires or the like. A lead frame may be used. On encapsulated members such as the power semiconductor chips 1, the stacked substrate 5, the chip bonding layer 27, the cooling device bonding layer 28, the metal wiring, etc., a primer layer may be stacked to enhance adhesion. Further, the case is filled with an encapsulating resin (not depicted). The depicted configuration of the power semiconductor module 50 is one example and the present invention is not limited to the depicted configuration.

In the present embodiment, the power semiconductor chips 1 are power chips such as MOSFETs (Metal Oxide Semiconductor Field Effect Transistors: insulated-gate-type field effect transistors), IGBTs (Insulated Gate Bipolar Transistors), SBDs (Schottky Barrier Diodes), etc. containing Si, SiC, or the like, and as a semiconductor substrate, a device using Si, SiC may be used. The number of the power semiconductor chips 1 mounted may be one or more than one.

At back surfaces of the power semiconductor chips 1, like conventionally, a metal electrode containing AlSi is provided when the semiconductor substrate contains Si and a metal electrode containing Ni is provided when the semiconductor substrate contains SiC (in either case, the metal electrode is not depicted herein), and between the metal electrode and the chip bonding layer 27 constituted by solder, a Ti layer and an Ni layer are stacked in the order stated. Furthermore, between the Ni layer and the chip bonding layer 27, an Au layer may be stacked (refer to FIG. 6).

The stacked substrate 5 may be configured by the insulating substrate 2, the first conductive plate 3 formed in a predetermined shape at one main surface of the insulating substrate 2, and the second conductive plate 4 formed at the other main surface of the insulating substrate 2. The first conductive plate 3 is formed in a predetermined circuit pattern at the front surface (first main surface) of the insulating substrate 2. The second conductive plate 4 may be a metal foil formed in an entire area of the back surface of the insulating substrate 2. For the insulating substrate 2, materials with favorable electrical insulation and thermal conductivity may be used. For example, Al₂O₃, AlN, SiN or the like may be used as a material of the insulating substrate 2. In particular, in high-voltage applications, while a material achieving both electrical insulation and thermal conductivity is desirable and thus, AlN or SiN may be used, the material is not limited hereto. Cu (copper) or a Cu alloy may be used for the first conductive plate 3 and the second conductive plate 4. Here, a Cu alloy is an alloy containing at least 80% Cu. Among such conductive plates containing Cu or a Cu alloy, a conductive plate not in contact with the power semiconductor chips 1 may be referred to as a back copper foil or a back conductive plate. A method of disposing the conductive plate on the insulating substrate 2 may be a direct copper bonding method or an active metal brazing method. Further, at the surface of the conductive plate, Ni (nickel) plating or the like may be performed and Ni or an Ni alloy may be formed.

The cooling device 26 has multiple heat dissipating fins and a heat sink containing a metal such as Cu or Al having favorable thermal conductivity, the heat sink having, for example, a substantially rectangular shape in a plan view. A front surface of the heat sink of the cooling device 26 may be covered with an Ni film or an Ni alloy film having an anticorrosion effect. A back surface the heat sink of the cooling device 26 may be bonded to the heat dissipating fins. The cooling device 26 is a cooling apparatus that, via the heat dissipating fins, dissipates heat generated by the power semiconductor chips 1 and transmitted by the stacked substrate 5.

The cooling device bonding layer 28 may be formed using a lead-free solder. For example, without limitation hereto, a Sn—Sb (antimony), a Sn—Cu, a Sn—Ag (silver), a Sn—Sb—Ag, or the like may be used. In particular, a preferable composition may contain 5 mass % to 10 mass % of Sb, 2 mass % to 5 mass % of Ag, 0.1 mass % to 0.4 mass % of Ni, 0.001 mass % to 0.1 mass % of Ge, and remainder mass % being Sn. More preferably, the solder may contain 0 to 2 mass % of Cu. Further, when the Cu content is 2 mass % or less, the Cu—Sn compound phase is promoted and thus, desirable. Further, the cooling device bonding layer 28 may be formed using a connecting material containing fine metal particles such as nano silver particles. Further, thermal grease or the like may be used.

The chip bonding layer 27 is formed using a lead-free solder. The chip bonding layer 27 is formed using a solder having a composition of Sn-(6-8.5]Sb-[2-4.5]Ag-[1.25-2.0]Cu. This composition contains Sb in a range of more than 6 mass % but not more than 8.5 mass %, Ag in a range of 2 mass % to 4.5 mass %, Cu in a range of 1.25 mass % to 2.0 mass %, and Sn constituting the remaining mass %. The composition may contain unavoidable impurities and Ge (germanium), P (phosphorus) may be further added in a range of more than 0.001 mass % but not more than 0.1 mass %. A solder material of the described composition may be a plate-type solder material obtained by melting so as to have a predetermined composition or may be a paste solder obtained by mixing a granular solder material and a flux material having a chemical reduction effect.

FIG. 2 is a cross-sectional view depicting the bonding layer, which is constituted by solder and between the first conductive plate and the power semiconductor chips of the power semiconductor module according to the embodiment. In the embodiment, Cu is added to the solder. The Cu in the solder diffuses as indicated by an arrow in FIG. 2. Cu diffuses more rapidly than Ni and thus, Cu from the solder reaches an interface with the Ni layer and forms a SnCu alloy 33 at the Ni layer. The SnCu alloy 33 becomes a protective layer with respect to the Ni layer and may suppress diffusion of Ni (formation of a SnNi alloy). Thus, an Ni residual film 34 remains without the Ni disappearing. It is presumed that wetting of the solder is ensured by the Ni residual film 34 and the occurrence of voids may be prevented. Cu and Sn in the solder more easily form a SnCu alloy at the Ni interface than inside the solder. Further, the Ni layer corresponds to the Ni layer 131 in FIG. 6 or the Ni residual film 134 in FIG. 7. More Cu is supplied to the chip bonding layer 27 (solder) when Cu (copper) or a Cu alloy is exposed at the first conductive plate 3 than when an Ni alloy layer (plating layer) is formed at the surface of the first conductive plate 3 and thus, effects of the present invention are facilitated.

In particular, when the first conductive plate 3 contains Cu or a Cu alloy, the Cu contained in the first conductive plate 3 also diffuses upward (toward the power semiconductor chips 1) and forms the SnCu alloy 33 at the Ni layer, whereby a greater amount of the SnCu alloy 33 is generated, enabling further suppression of the diffusion of Ni.

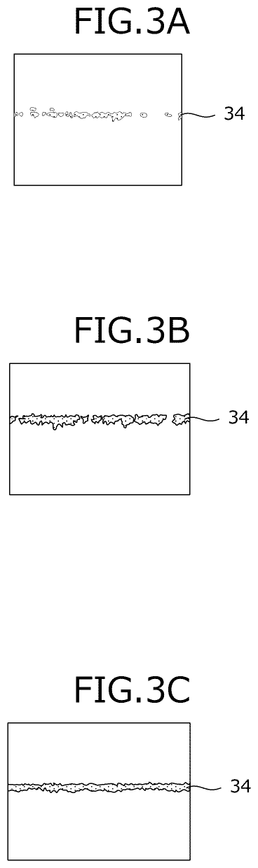

FIGS. 3A, 3B, and 3C are cross-sectional views depicting the Ni residual film of the bonding layer constituted by a solder obtained by adding Cu to a Sn—Sb—Ag based solder. The thickness of the Ni layer before bonding is 0.7 μm. FIG. 3A is an instance in which 0 mass % Cu is added; FIG. 3B is an instance in which 0.9 mass % Cu is added; and FIG. 3C is an instance in which 2.0 mass % Cu is added. These figures depict results of mapping Ni by incorporating EDX (energy dispersive X-ray spectroscopy) into a SEM (scanning electron microscope).

In the instance in which no Cu is added in FIG. 3A, there are numerous locations where the Ni residual film 34 disappears and even in the instance in which the added Cu is 0.9 mass % in FIG. 3B, there are locations where the Ni residual film 34 disappears. On the other hand, as depicted in FIG. 3C, in the instance in which the added Cu is 2.0 mass %, the Ni residual film 34 does not disappear and it is possible to obtain the Ni residual film 34 that is stable, by increasing the amount of Cu added.

Reliability of the power semiconductor module according to the embodiment was confirmed by a power cycling test. Here, the reliability was evaluated by the power cycling capability (TjP/C capability) with respect to the amount of Cu added to the solder. The power cycling test was performed over a range of 50 degrees C. to 150 degrees C. (ΔTj=100 degrees C.) to investigate the number of cycles before electrical characteristics exhibited abnormal values. In particular, the power semiconductor module was energized so that 150 degrees C. was reached from a state of 50 degrees C. and failure was judged to be when the thermal resistance value increased 20% from the initial value. The power cycling test (P/C) was performed with respect to multiple power semiconductor modules; a cumulative defect percentage is the cumulative percentage of the number of failed modules; and the number of cycles when the cumulative defect percentage becomes 1% is called the P/C capability. When the P/C capability is 60k cycles or greater, the module is determined to be reliable and when the P/C capability is less than 60k cycles, the module is judged to be unreliable.

For example, results of a power cycling test using solder with a composition of Sn-8Sb-3Ag-1.3Cu-0.003Ge and results of a power cycling test using a solder with a composition of Sn-8Sb-3Ag-0.9Cu-0.003Ge are depicted. The number of cycles when the cumulative defect percentage becomes 1% is about 85000 cycles in the case of Sn-8Sb-3Ag-1.3Cu-0.003Ge and about 100000 cycles in the case of Sn-8Sb-3Ag-0.9Cu-0.003Ge; thus, the power semiconductor module is reliable in both cases. While the module is reliable in both cases, when the amount of Cu is greater, the number of cycles when the cumulative defect percentage becomes 1% is lower. Therefore, it is understood that when the amount of added Cu is excessive, the P/C capability of the power semiconductor module decreases.

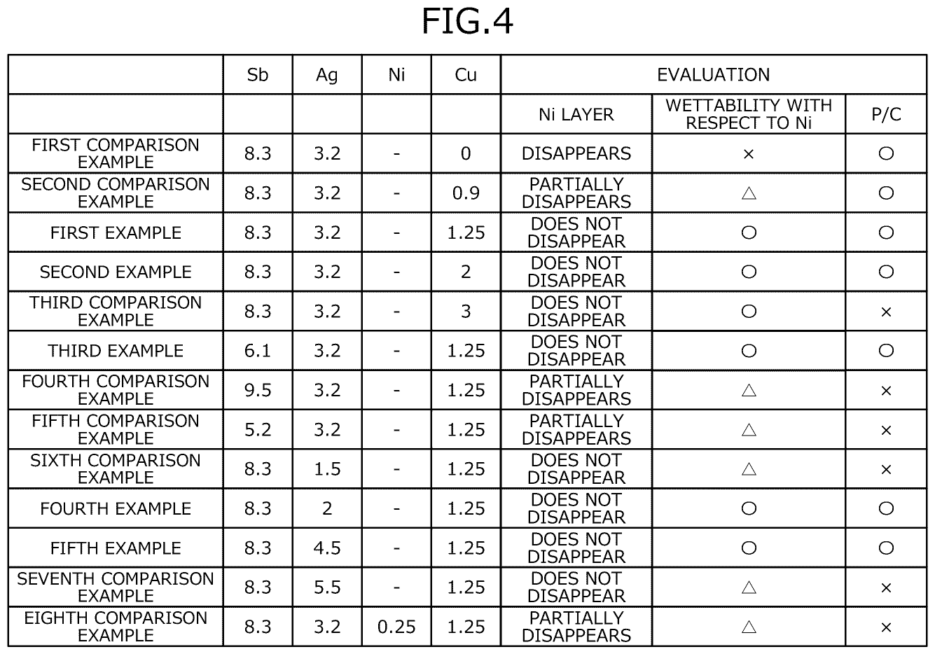

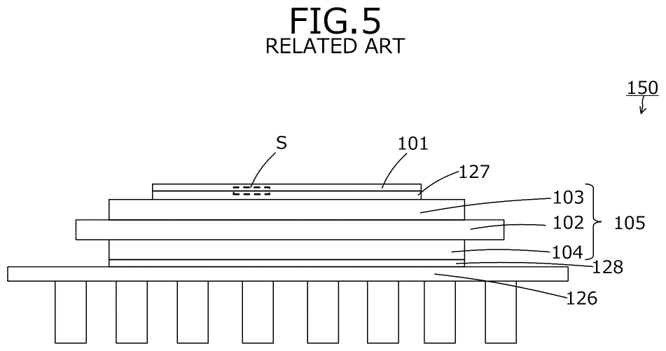

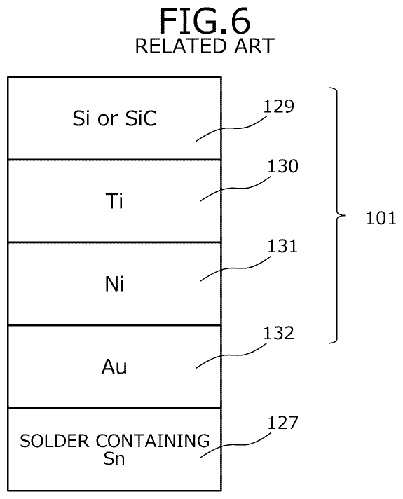

FIG. 4 is a table showing evaluation results for power semiconductor modules of comparison examples and examples, for each solder composition. In FIG. 4, the Ni layer was evaluated by the thickness of the Ni residual film after bonding. Wettability with respect to Ni (chip back surface) was determined by observing voids of the chip bonding layer 27 by a SAT (ultrasonic defect detection). When the wettability is poor, voids and the like occur at the interface with the surface that is to be bonded, whereby the initial thermal resistance increases and thus, is undesirable. A void of a size exceeding 1.3% of the area of the bonding surface of one of the power semiconductor chips 1 increases the thermal resistance and is evaluated as “x” while a void of a size 0.3% or less of the area is evaluated as “∘”. When the size is greater than 0.3% but less than 1.3%, while there are no major problems at this time, there is concern of the thermal resistance increasing when the capacity is greater and thus, is evaluated as “Δ”. Further, as for evaluation of the P/C (power cycling test), a P/C capability of 60k cycles or greater is assumed to be reliable (∘) while less than 60k cycles is assumed to be unreliable (x).

With respect to first and second examples and first to third comparison examples, effects of Cu addition were evaluated using a solder composition of Sn-8.3Sb-3.2Ag-xCu. In the first comparison example, the amount of Cu added is 0 mass % and as described above, when the amount of added Cu is small, formation of the SnCu alloy is low, the Ni residual film disappears, and the evaluation of the wettability with respect to Ni is “x”. In the second comparison example, the amount of Cu added is 0.9 mass % and in this case as well, the Ni residual film partially disappears, and the evaluation of the wettability with respect to Ni is “Δ”. Even when the evaluation of the P/C is “∘”, in a portion, there are locations where the Ni film disappears and with harsher P/Cs, the reliability is likely to decrease. In the third comparison example, the amount of Cu is 3 mass % and when the amount of Cu added is large, the SnCu alloy becomes coarse, thereby reducing the strength of the SnCu alloy, whereby cracking occurs. Therefore, the evaluation of the P/C is “x”.

The first and second examples are cases in which the amount of Cu added is 1.25 mass % and 2 mass %, respectively, and in both cases, the evaluation of the wettability with respect to Ni and the evaluation of the P/C are “∘”. From the results, in the solder of the embodiment, Cu is added within a composition % range of 1.25 mass % to 2.0 mass %.

With respect to the first and third examples and fourth and fifth comparison examples, effects of Sb addition were evaluated using a solder composition of Sn-xSb-3.2Ag-1.25Cu. In the first example, the amount Sb added is 8.3 mass % while in the third example, the amount of Sb added is 6.1 mass % and in both examples, there is no disappearance of the Ni residual film and the evaluation of the wettability with respect to Ni and the evaluation of the P/C are “∘”. This is presumed to result because when the amount of Sb is suitable, a SnSb alloy is formed, the SnNi alloy decreases, and eating away of Ni decreases. In the fourth comparison example, the amount of Sb added is 9.5 mass %, the Ni residual film partially disappears, and the evaluation of the wettability with respect to Ni is “Δ” while the evaluation of the P/C is “x”. This is presumed to result because when Sb is in excess, a large amount of the SnSb alloy is formed, formation of the SnCu alloy at the chip back surface is difficult, eating away of Ni occurs, and the wettability is poor. Further, when there is a large amount of Sb and bonding is performed at a cooling rate of a normal solder, for example, not more than 20 degrees C./sec, a Sb₃Sn₂ compound crystalizes in a SnSb peritectic structure having Sb as a nucleus. Crystallization of the Sb₃Sn₂ compound enhances strength but reduces ductility. Further, when thermal deformation and distortion accompanying heat generation are applied, the compound moves to grain boundaries and the SbSn alloy becomes coarse due to mutual diffusion with Sn. This coarse compound reduces the grain boundary strength, which facilitates grain boundary slippage, leading to generation of cavities at the grain boundaries, decreases in ductility, and decreases in strength. As described, both strength and ductility cannot be obtained, and the evaluation of the P/C is presumed to be “x”. In the fifth comparison example, the amount of Sb added is 5.2 mass %, the Ni residual film partially disappears, the evaluation of the wettability with respect to Ni is “Δ”, and the evaluation of the P/C is “x”. This is presumed to result because when there is a small amount of Sb, a small amount of a SnSb alloy is formed, formation of a SnNi alloy is facilitated, eating away of Ni increases, and wettability becomes poor. Further, it is presumed that a small amount of a SnSb alloy is formed and thus, bonding strength decreases and the evaluation of the P/C is “x”. From the results, in the solder of the embodiment, Sb is added within a composition % range of more than 6 mass % but not more than 8.5 mass %.

With respect to the first, fourth, and fifth examples and sixth and seventh comparison example, effects of Ag addition were evaluated using a solder composition of Sn-8.3Sb-xAg-1.25Cu. In the first, fourth, and fifth examples, the amount of Ag added is 3.2 mass %, 2 mass %, and 4.5 mass %, respectively, the Ni residual film does not disappear, the evaluation of the wettability with respect to Ni is “∘”, and the evaluation of the P/C is “∘”. In the sixth comparison example, the amount of Ag added is 1.5 mass %, the Ni residual film does not disappear, the evaluation of the wettability with respect to Ni is “Δ”, and the evaluation of the P/C is “x”. This is presumed to result because when the amount of Ag is small, the wettability with respect to Ni is poor, a small amount of a SnAg alloy is formed, and the strength decreases. In the seventh comparison example, the amount of Ag added is 5.5 mass %, the Ni residual film does not disappear, the evaluation of the wettability with respect to Ni is “Δ”, and the evaluation of the P/C is “x”. This presumed to occur because when the amount of Ag is large, the wettability of the Ni film is poor, and when the amount of Ag is greater than 5.0 mass %, a hypereutectic system is formed, a eutectic system of βSn and Ag₃Sn with an excess amount of Ag becomes denser, and the strengthened precipitation structure becomes excessive. Further, a distance between AgsSn and BSn decreases due to the network structure of AgsSn and BSn, whereby AgsSn looks like a large compound and large hard compounds are scattered. A compound in which AgsSn is an apparent mass is subjected to a heat treatment, external force, or the like and thereby diffuses with Sn and Ag and becomes a large AgsSn compound. It is presumed that this makes it impossible to obtain a stable, uniform solidification structure, impossible to obtain both strength and ductility, and impossible to enhance bonding strength, resulting in brittleness. From the results, in the solder of the embodiment, Ag is added within a composition % range of 2 mass % to 4.5 mass %.

With respect to an eighth comparison example, effects of Ni addition were evaluated using a solder composition of Sn-8.3Sb-3.2Ag-1.25Cu-0.25Ni. In the eighth comparison example, the amount of Ni added is 0.25 mass %, the Ni residual film partially disappears, the evaluation of the wettability with respect to Ni is “Δ”, and the evaluation of the P/C is “x”. This is presumed to result because when Ni is present, a SnNi alloy is also formed on the first conductive plate, whereby diffusion of Cu from the first conductive plate is inhibited and formation of a SnCu alloy becomes difficult and thus, a measure against Ni disappearing is not obtained. Further, it is assumed that due to attachment of Ni, the solder becomes brittle and reliability decreases. From the results, in the embodiment, the solder contains no additional Ni above an inevitable amount of the impurity.

Next, a method of manufacturing the power semiconductor module according to the embodiment is described. First, the cooling device 26 is bonded to the second conductive plate 4 of the stacked substrate 5 by the cooling device bonding layer 28. Next, a solder with a composition of Sn-(6-8.5]Sb-[2-4.5]Ag-[1.25-2.0]Cu is applied to or disposed on the first conductive plate 3 of the stacked substrate 5. Next, the power semiconductor chips 1 are placed on the solder. At this time, pressure may be applied from above the power semiconductor chips 1. Preferably, this pressure may be in a range of 1 kPa to 20 kPa and more preferably, may be in a range of 5 kPa to 10 kPa. By setting the pressure to be within these ranges, voids are reduced and Ni diffusion may be prevented. As a result, the power semiconductor chips 1 are heated and bonded to the first conductive plate 3 of the stacked substrate 5 by the chip bonding layer 27. The rate of temperature increase of the heat treatment may be about 1 degree C./second and preferably, the rate of temperature decrease may be 5 degrees C./second or more, however, a range of 8 degrees C./second to 15 degrees C./second facilitates finer crystals and enhances bonding strength and thus, is more preferable.

Subsequently, the case is mounted to the cooling device 26 and thereafter, bonding of the lead frame and wire bonding by metal wiring are performed. Next, a primer layer may be formed. Next, the case is filled with an encapsulating resin, the encapsulating resin is pre-cured for 10 minutes to 120 minutes in a range of 100 to 120 degrees C. and is cured for 1 hour to 2 hours in a range of about 175 degrees C. to 185 degrees C. Thus, the power semiconductor module according to the embodiment is manufactured.

As described, according to the solder, the semiconductor module and the method of manufacturing a semiconductor module of the embodiment, the first conductive plate and the power semiconductor chip are bonded by the solder having a composition of Sn-(6-8.5]Sb-[2-4.5]Ag-[1.25-2.0]Cu. As a result, Cu from the solder reaches the interface of the Ni layer, and a SnCu alloy is formed at the interface of the Ni layer and becomes a protective layer for the Ni layer, thereby, enabling suppression of Ni diffusion. Thus, an Ni residual film remains without the Ni disappearing. The Ni residual film ensures the wettability of the solder, whereby the occurrence of voids may be prevented.

In the foregoing, the present invention may be variously modified within a range not departing from the spirit of the invention and in the described embodiments, for example, dimensions, doping concentrations, etc. of regions, etc. may be variously set according to necessary specifications.

According to the invention described, the stacked substrate and the power semiconductor chip are bonded by a solder having a composition of Sn-(6-8.5]Sb-[2-4.5]Ag-[1.25-2.0]Cu. As a result, Cu from the solder reaches an interface of an Ni layer, a SnCu alloy is formed at the interface of the Ni layer and becomes a protective layer for the Ni layer, thereby enabling suppression of Ni diffusion. Thus, an Ni residual film remains without the Ni disappearing. The Ni residual film ensures the wettability of the solder, whereby the occurrence of voids may be prevented. The solder having the composition containing Sb in a range of more than 6 mass % but not more than 8.5 mass %, Ag in a range of 2 mass % to 4.5 mass %, Cu in a range of 1.25 mass % to 2.0 mass %, a remaining portion of the compositions constituted by Sn and an inevitable impurity is indicated herein as Sn-(6-8.5]Sb-[2-4.5]Ag-[1.25-2.0]Cu and hereinafter, notation of other compositions are similarly indicated.

The semiconductor module and the method of manufacturing a semiconductor module according to the present invention achieve an effect in that an occurrence of voids at the bonding layer may be prevented.

As described, the semiconductor module and the method of manufacturing a semiconductor module according to the present invention are useful for power semiconductor modules used in power converting equipment such as inverters, power source devices of various types of industrial machines, igniters of automobiles, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor module, comprising:
a stacked substrate;
a semiconductor device element mounted on the stacked substrate, the semiconductor device element having an Ni layer at a back surface thereof; and
a solder bonding the back surface of the semiconductor device element to the stacked substrate, the solder being formed of a composition containing:
Sb in a range of more than 6 mass % but not more than 8.5 mass %,
Ag in a range of 2 mass % to 4.5 mass %,
Cu in a range of 1.25 mass % to 2.0 mass %, and
Sn as a remaining portion thereof.

2. The semiconductor module according to claim 1, wherein the composition of the solder is free of Ni.

3. The semiconductor module according to claim 1, wherein the stacked substrate includes a conductive plate facing the semiconductor device element, the conductive plate containing copper or a copper alloy.

4. A method of manufacturing a semiconductor module, the method comprising:
preparing a stacked substrate;
applying a solder to the stacked substrate, the solder being formed of a composition containing:
Sb in a range of more than 6 mass % but not more than 8.5 mass %,
Ag in a range of 2 mass % to 4.5 mass %,
Cu in a range of 1.25 mass % to 2.0 mass %, and
Sn as a remaining portion thereof; and
placing a semiconductor device element on the solder so as to bond a back surface of the semiconductor device element to the stacked substrate, an Ni layer being at the back surface.
